(19) United States
(12) Patent Application Publication
(10) Pub. No.: US 2010/0171211 A1
(43) Pub. Date: Jul. 8, 2010

(54) SEMICONDUCTOR DEVICE

(76) Inventors: Che-Yuan Jao, Hsinchu City (TW); Sheng-Ming Chang, Taipei County (TW)

Correspondence Address: NORTH AMERICA INTELLECTUAL PROPERTY CORPORATION, P.O. BOX 506, MERRIFIELD, VA, 22116, US

(21) Appl. No.: 12/350,208

(22) Filed: Jan. 7, 2009

(51) Int. Cl. H01L 23/488

(52) U.S. Cl. 257/690; 257/738; 257/E23.023

(57) ABSTRACT

A semiconductor device is provided by the present invention. The semiconductor device includes a semiconductor die, and the semiconductor die includes a die core having at least two bond pads with voltage level equivalent to each other and electrically connected to each other via at least a bond wire, and an input/output (I/O) periphery. The semiconductor device of the present invention is capable of solving the IR drop of the semiconductor die with low cost.

### BACKGROUND

The present invention relates to a semiconductor device, and more particularly, to a semiconductor device capable of eliminating voltage (IR) drop of the semiconductor die.

Many conventional semiconductor devices are mounted in packages such as Quad Flat Packs (QFPs) and Pin Ball Gate Arrays (PBGAs) in which the input and output terminals are arranged along the edge of the semiconductor die. Arranging the terminals along the semiconductor die edge may result in relatively long wirings on silicon to supply power and ground to the center of the semiconductor die. These long wirings generally have a relatively high resistance leading to the unacceptable IR drops.

There are several conventional approaches for solving IR drop of the semiconductor dies. For example, one of the conventional approaches is increasing metal layers to decrease overall resistance of the semiconductor dies; another one of the conventional approaches is increasing metal thickness to decrease overall resistance of the semiconductor dies; and the other one of the conventional approaches is using the flip chip technology to connect chip internal nodes directly.

However, the conventional approaches of increasing the metal layers and using the flip chip technology cost a lot, and the conventional approach of increasing the metal thickness help little.

### SUMMARY OF THE INVENTION

It is therefore one of the objectives of the invention to provide a semiconductor device capable of eliminating voltage (IR) drop of the semiconductor die, so as to solve the above problem.

In accordance with an embodiment of the invention, a semiconductor device is disclosed. The semiconductor device includes a semiconductor die, and the semiconductor die includes a die core having at least two bond pads with voltage level equivalent to each other and electrically connected to each other via at least a bond wire, and an input/output (I/O) periphery.

In accordance with an embodiment of the invention, a semiconductor device is further disclosed. The semiconductor device includes a first semiconductor die and a second semiconductor die. The first semiconductor die includes a first die core having at least a bond pad, and a first input/output (I/O) periphery having at least an I/O bond pad. The second semiconductor die includes a second die core having at least a bond pad with voltage level equivalent to the bond pad of the first die core, and a second I/O periphery having at least an I/O bond pad, wherein the bond pad of the first die core is electrically connected to the bond pad of the second die core via at least a bond wire.

In accordance with an embodiment of the invention, a semiconductor device is yet further disclosed. The semiconductor device includes a first semiconductor die and a second semiconductor die. The first semiconductor die includes a first die core having at least a bond pad, and a first input/output (I/O) periphery having at least an I/O bond pad. The second semiconductor die includes a second die core having at least a bond pad with voltage level equivalent to the bond pad of the first die core, and a second I/O periphery having at least an I/O bond pad with voltage level equivalent to the bond pad of the first die core, wherein the bond pad of the first die core is electrically connected to the I/O bond pad of the second I/O periphery via at least a bond wire.

In accordance with an embodiment of the invention, a semiconductor device is yet further disclosed. The semiconductor device includes a semiconductor die and a dummy die. The semiconductor die includes a die core having at least a bond pad, and an input/output (I/O) periphery. The dummy die has at least a bond pad with voltage level equivalent to the bond pad of the die core of the semiconductor die, wherein the bond pad of the die core of the semiconductor die is electrically connected to the bond pad of the dummy die via at least a bond wire.

In accordance with an embodiment of the invention, a semiconductor device is yet further disclosed. The semiconductor device includes a semiconductor die and a metal film. The semiconductor die includes a die core having at least a bond pad, and an input/output (I/O) periphery. The metal film has at least a bond pad with voltage level equivalent to the bond pad of the die core of the semiconductor die, wherein the bond pad of the die core of the semiconductor die is electrically connected to the bond pad of the metal film core via at least a bond wire.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a simplified diagram of a semiconductor device in accordance with a first embodiment of the present invention.

FIG. 2 shows a first variation of the semiconductor device shown in FIG. 1.

FIG. 3 shows a second variation of the semiconductor device shown in FIG. 1.

FIG. 4 shows a simplified diagram of a semiconductor device in accordance with a second embodiment of the present invention.

FIG. 5 shows a first variation of the semiconductor device shown in FIG. 4.

FIG. 6 shows a second variation of the semiconductor device shown in FIG. 4.

FIG. 7 shows a third variation of the semiconductor device shown in FIG. 4.

FIG. 8 shows a simplified diagram of a semiconductor device in accordance with a third embodiment of the present invention.

FIG. 9 shows a simplified diagram of a semiconductor device in accordance with a fourth embodiment of the present invention.

FIG. 10 shows a first variation of the semiconductor device shown in FIG. 9.

FIG. 11 shows a second variation of the semiconductor device shown in FIG. 9.

FIG. 12 shows a third variation of the semiconductor device shown in FIG. 9.

FIG. 13 shows a simplified diagram of a semiconductor device in accordance with a fifth embodiment of the present invention.

FIG. 14 shows a simplified diagram of a semiconductor device in accordance with a sixth embodiment of the present invention.

FIG. 15 shows a first variation of the semiconductor device shown in FIG. 14.

FIG. 16 shows a second variation of the semiconductor device shown in FIG. 14.

### DETAILED DESCRIPTION

Certain terms are used throughout the following description and the claims to refer to particular system components. As one skilled in the art will appreciate, manufacturers may refer to a component by different names. This document does not intend to distinguish between components that differ in name but not function. In the following discussion and in the claims, the terms “include”, “including”, “comprise”, and “comprising” are used in an open-ended fashion, and thus should be interpreted to mean “including, but not limited to . . . ” The terms “couple” and “coupled” are intended to mean either an indirect or a direct electrical connection. Thus, if a first device couples to a second device, that connection may be through a direct electrical connection, or through an indirect electrical connection via other devices and connections.

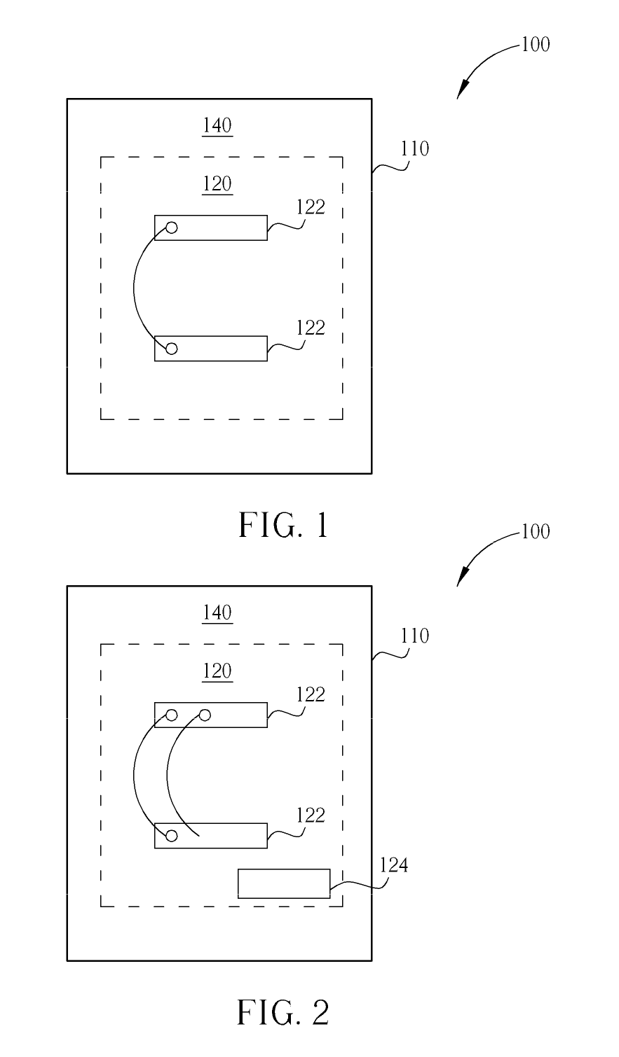

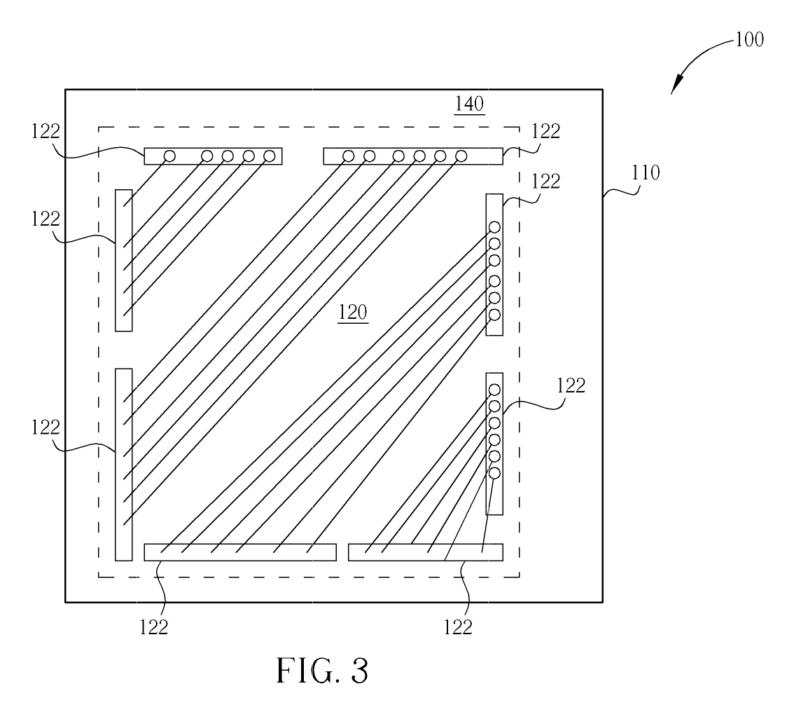

Please refer to FIG. 1. FIG. 1 shows a simplified diagram of a semiconductor device 10 in accordance with a first embodiment of the present invention. As shown in FIG. 1, the semiconductor device 10 comprises a semiconductor die 100, and the semiconductor die 100 comprises a die core 120 and an input/output (I/O) periphery 140. The die core 120 has at least two bond pads 122 with voltage level equivalent to each other and electrically connected to each other via at least a bond wire so as to solve the voltage (IR) drop of the semiconductor die 100. For example, please refer to FIG. 2. FIG. 2 shows a first variation of the semiconductor device 10. As shown in FIG. 2, the bond pads 122 can be electrically connected to each other via a plurality of bond wires, and one of the bond pads 122 can comprise at least a multiple bond site. The bond pads 122 can use a wire bond type selected from the group consisting of ball bonds, stitch bonds on bonding pad, and stitch bonds on ball. The die core 120 also can further comprise a spare pad opening 124. In addition, the semiconductor device 10 also can be designed to form a shield wire array for EMI noise rejections as shown in FIG. 3. Please note that the above embodiments are only for illustration purposes and are not meant to be limitations of the present invention.

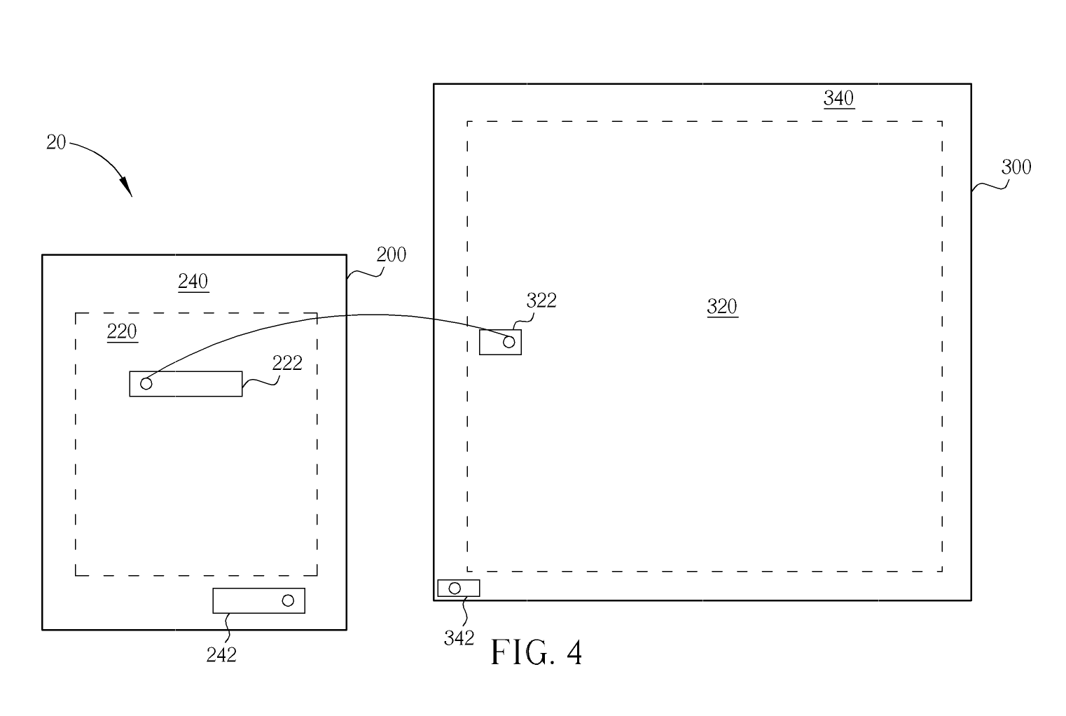

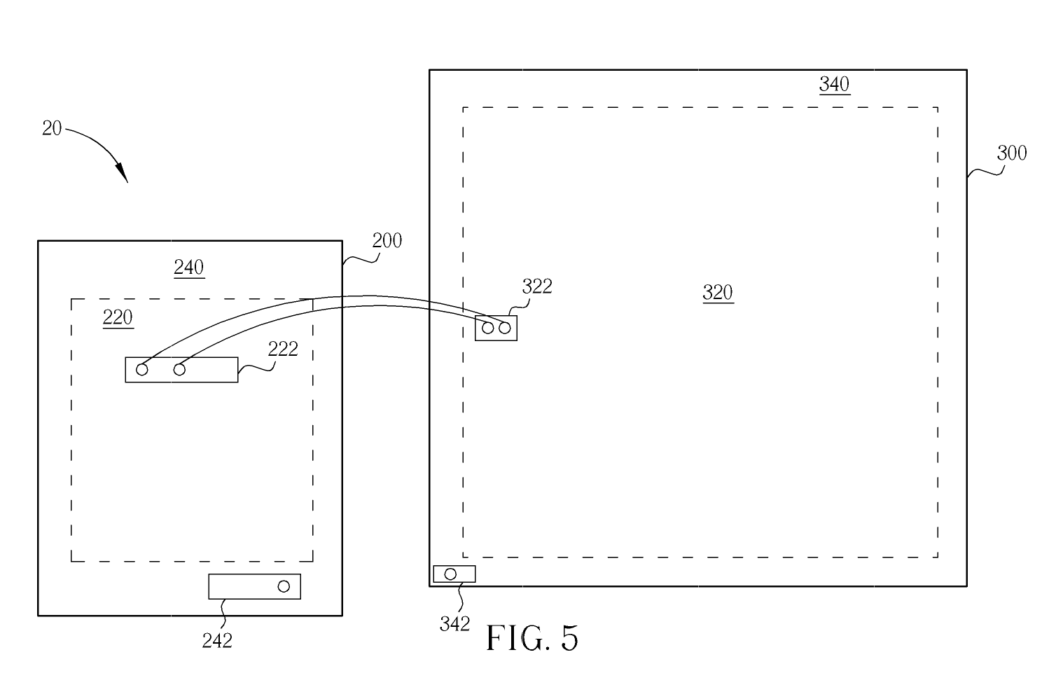

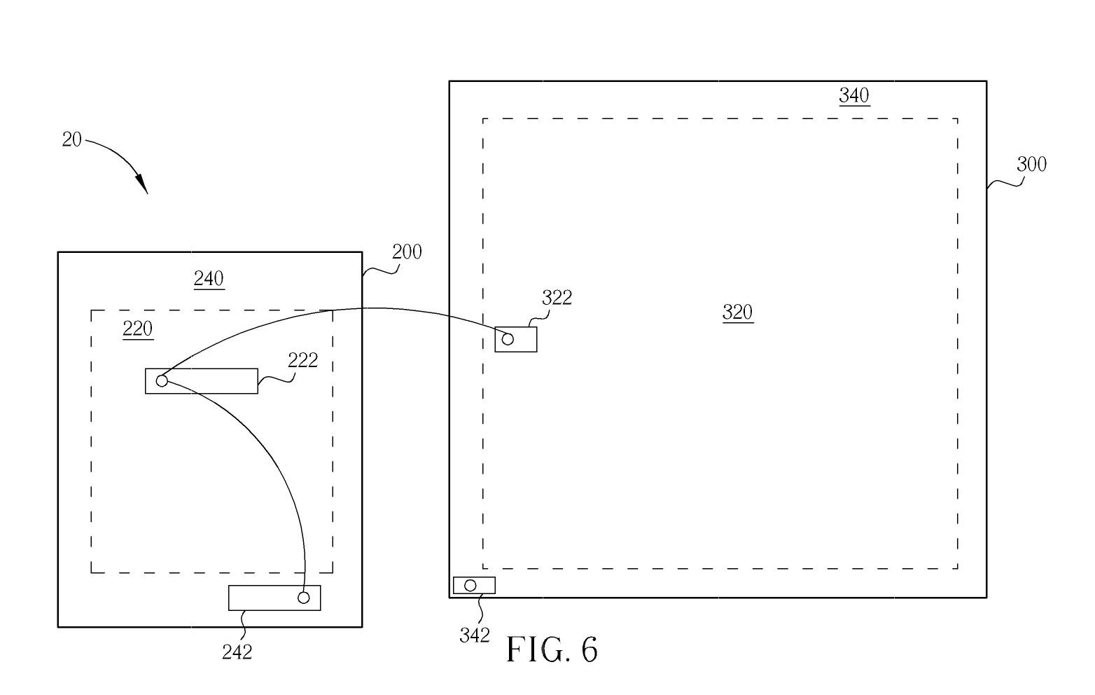

Please refer to FIG. 4. FIG. 4 shows a simplified diagram of a semiconductor device 20 in accordance with a second embodiment of the present invention. As shown in FIG. 4, the semiconductor device 20 comprises a first semiconductor die 200 and a second semiconductor die 300, wherein the first semiconductor die 200 and the second semiconductor die 300 are disposed side by side. The first semiconductor die 200 comprises a first die core 220 having at least a bond pad 222, and a first input/output (I/O) periphery 240 having at least an I/O bond pad 242. The second semiconductor die 300 comprises a second die core 320 having at least a bond pad 322 with voltage level equivalent to the bond pad 222 of the first die core 220, and a second I/O periphery 340 having at least an I/O bond pad 342, wherein the bond pad 222 of the first die core 220 is electrically connected to the bond pad 322 of the second die core 320 via at least a bond wire so as to solve the IR drop of the first semiconductor die 200 and the second semiconductor die 300. For example, please refer to FIG. 5. FIG. 5 shows a first variation of the semiconductor device 20. As shown in FIG. 5, the bond pad 222 of the first die core 220 can be electrically connected to the bond pad 322 of the second die core 320 via a plurality of bond wires, and one of the bond pad 222 and the bond pad 322 can comprise at least a multiple bond site. The bond pad 222 and the bond pad 322 can use a wire bond type selected from the group consisting of ball bonds, stitch bonds on bonding pad, and stitch bonds on ball. Please note that the above embodiments are only for illustration purposes and are not meant to be limitations of the present invention.

Please refer to FIG. 6. FIG. 6 shows a second variation of the semiconductor device 20. As shown in FIG. 6, when the I/O bond pad 242 of the first I/O periphery 240 has voltage level equivalent to the bond pad 222 of the first die core 220, the I/O bond pad 242 can be electrically connected to the bond pad 222 via at least a bond wire. The bond pad 222 and the I/O bond pad 242 can use a wire bond type selected from a group consisting of ball bonds, stitch bonds on bonding pad, and stitch bonds on ball. In addition, the bond pad 222 also can be electrically connected to the I/O bond pad 242 via a plurality of bond wires, and one of the bond pad 222 and the I/O bond pad 242 can comprise at least a multiple bond site.

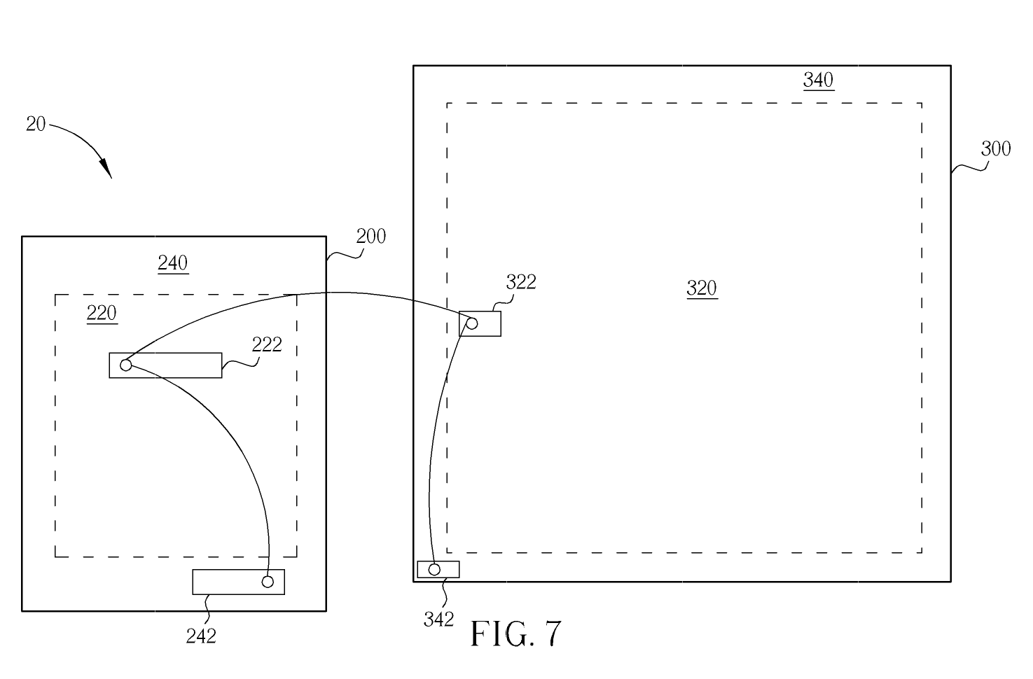

Please refer to FIG. 7. FIG. 7 shows a third variation of the semiconductor device 20. As shown in FIG. 7, when the I/O bond pad 242 of the first I/O periphery 240 has voltage level equivalent to the bond pad 222 of the first die core 220 and the I/O bond pad 342 of the second I/O periphery 340 has voltage level equivalent to the bond pad 322 of the second die core 320, the I/O bond pad 242 can be electrically connected to the bond pad 222 via at least a bond wire and the I/O bond pad 342 can be electrically connected to the bond pad 322 via at least a bond wire. The bond pad 222, the I/O bond pad 242, the bond pad 322, and the I/O bond pad 342 can use a wire bond type selected from a group consisting of ball bonds, stitch bonds on bonding pad, and stitch bonds on ball. In addition, the bond pad 222 also can be electrically connected to the I/O bond pad 242 via a plurality of bond wires, and one of the bond pad 222 and the I/O bond pad 242 can comprise at least a multiple bond site. The bond pad 322 also can be electrically connected to the I/O bond pad 342 via a plurality of bond wires, and one of the bond pad 322 and the I/O bond pad 342 can comprise at least a multiple bond site. Please note that the above embodiments are only for illustration purposes and are not meant to be limitations of the present invention.

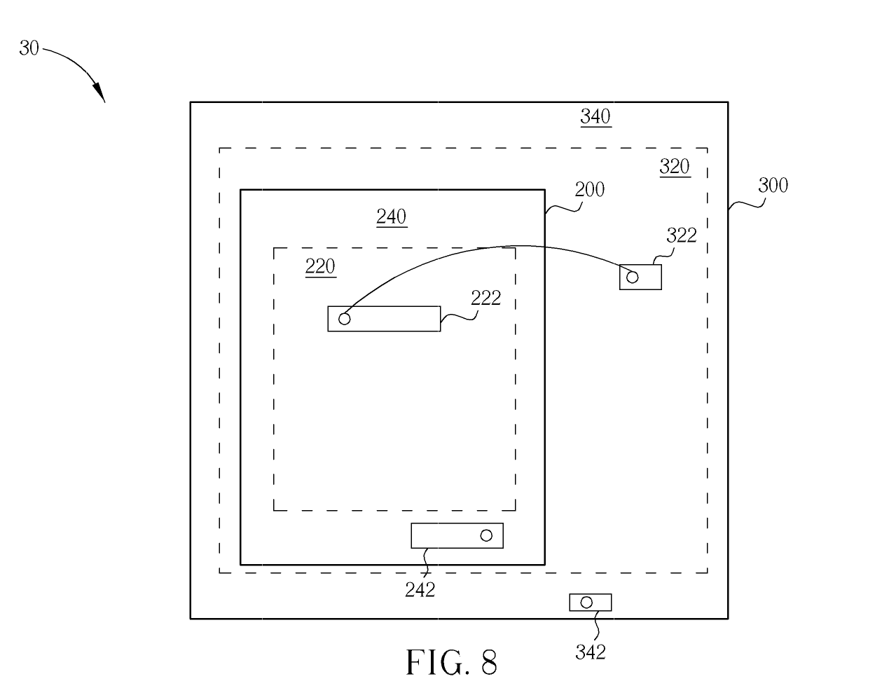

Please refer to FIG. 8. FIG. 8 shows a simplified diagram of a semiconductor device 30 in accordance with a third embodiment of the present invention. As shown in FIG. 8, the semiconductor device 30 also comprises the first semiconductor die 200 and the second semiconductor die 300 in the second embodiment of the present invention shown in FIG. 4, wherein the first semiconductor die 200 is stacked on the second semiconductor die 300. However, the other characteristics and the variations of the semiconductor device 30 are the same as those of the semiconductor device 20 in the second embodiment of the present invention, and thus further explanation of the details and operations are omitted herein for the sake of brevity.

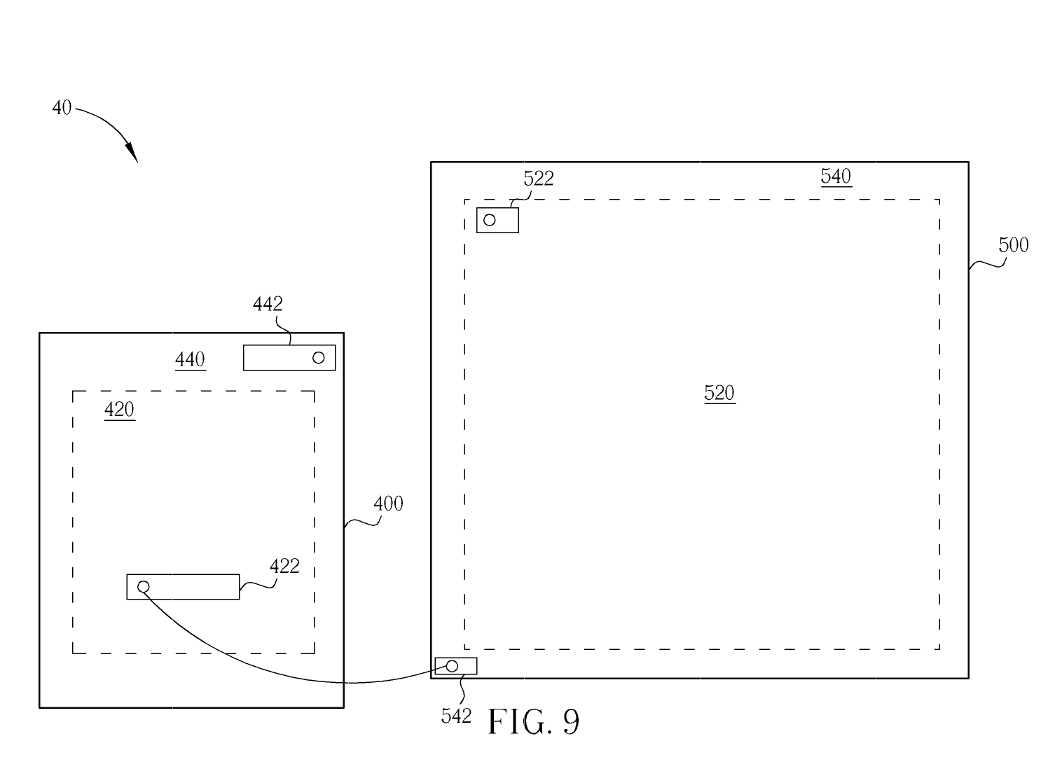

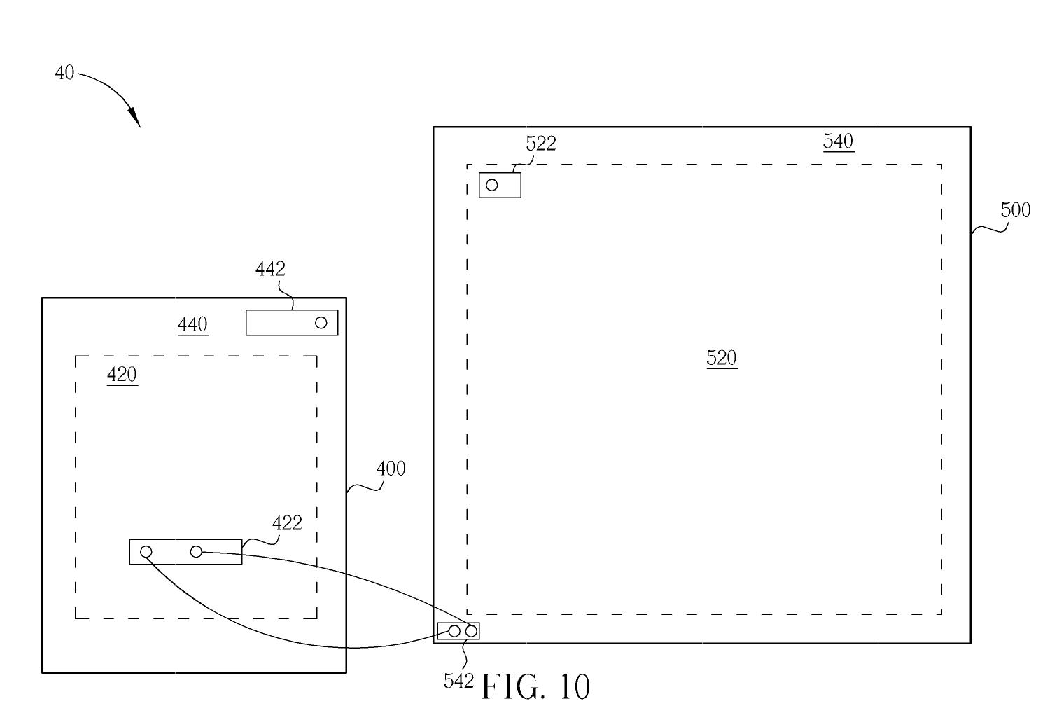

Please refer to FIG. 9. FIG. 9 shows a simplified diagram of a semiconductor device 40 in accordance with a fourth embodiment of the present invention. As shown in FIG. 9, the semiconductor device 40 comprises a first semiconductor die 400 and a second semiconductor die 500, wherein the first semiconductor die 400 and the second semiconductor die 500 are disposed side by side. The first semiconductor die 400 comprises a first die core 420 having at least a bond pad 422, and a first input/output (I/O) periphery 440 having at least an I/O bond pad 442. The second semiconductor die 500 comprises a second I/O periphery 540 having at least an I/O bond pad 542 with voltage level equivalent to the bond pad 422 of the first die core 420, and a second die core 520 having at least a bond pad 522, wherein the bond pad 422 of the first die core 420 is electrically connected to the I/O bond pad 542 of the second I/O periphery 540 via at least a bond wire so as to solve the IR drop of the first semiconductor die 400 and the second semiconductor die 500. For example, please refer to FIG. 10. FIG. 10 shows a first variation of the semiconductor device 40. As shown in FIG. 10, the bond pad 422 of the first die core 420 can be electrically connected to the I/O bond pad 542 of the second I/O periphery 540 via a plurality of bond wires, and one of the bond pad 422 and the I/O bond pad 542 can comprise at least a multiple bond site. The bond pad 422 and the I/O bond pad 542 can use a wire bond type selected from the group consisting of ball bonds, stitch bonds on bonding pad, and stitch bonds on ball. Please note that the above embodiments are only for illustration purposes and are not meant to be limitations of the present invention.

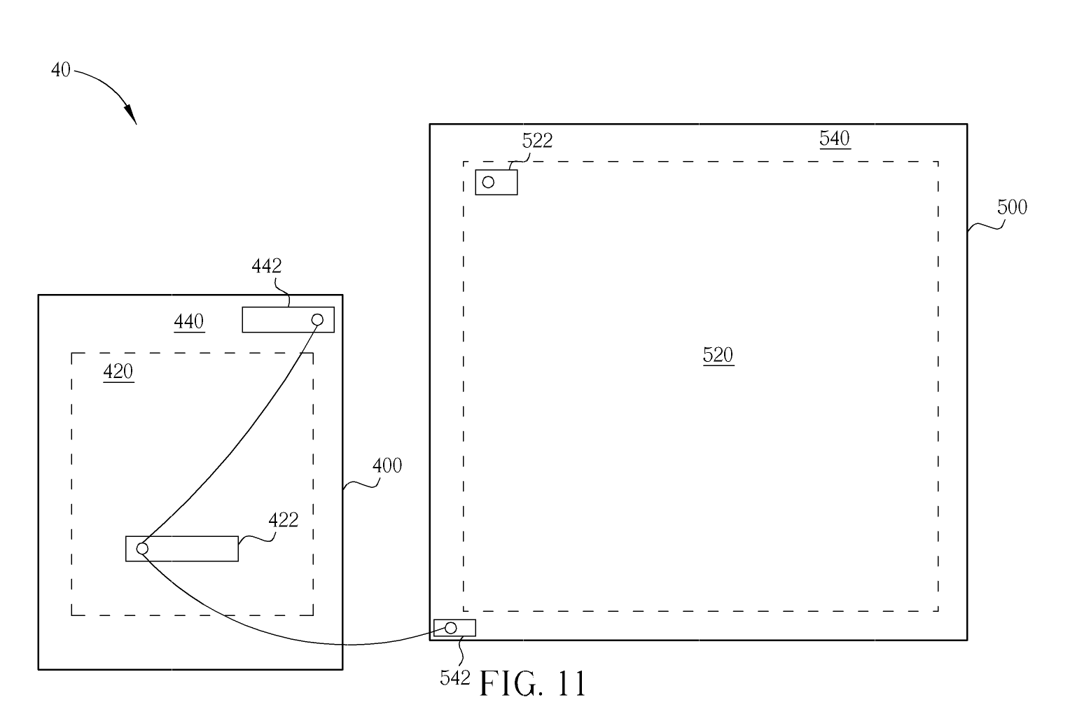

Please refer to FIG. 11. FIG. 11 shows a second variation of the semiconductor device 40. As shown in FIG. 11, when the I/O bond pad 442 of the first I/O periphery 440 has voltage level equivalent to the bond pad 422 of the first die core 420, the I/O bond pad 442 can be electrically connected to the bond pad 422 via at least a bond wire. The bond pad 422 and the I/O bond pad 442 can use a wire bond type selected from a group consisting of ball bonds, stitch bonds on bonding pad, and stitch bonds on ball. In addition, the bond pad 422 also can be electrically connected to the I/O bond pad 442 via a plurality of bond wires, and one of the bond pad 422 and the I/O bond pad 442 can comprise at least a multiple bond site.

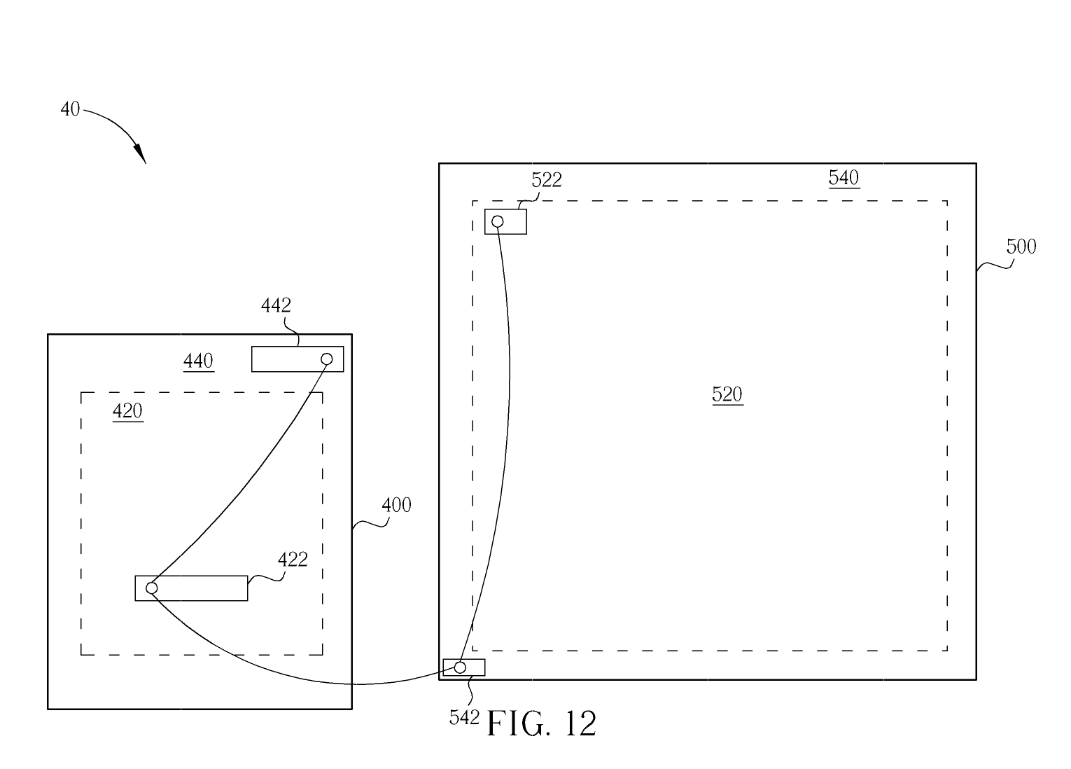

Please refer to FIG. 12. FIG. 12 shows a third variation of the semiconductor device 40. As shown in FIG. 12, when the I/O bond pad 442 of the first I/O periphery 440 has voltage level equivalent to the bond pad 422 of the first die core 420 and the I/O bond pad 542 of the second I/O periphery 540 has voltage level equivalent to the bond pad 522 of the second die core 520, the I/O bond pad 442 can be electrically connected to the bond pad 422 via at least a bond wire and the I/O bond pad 542 can be electrically connected to the bond pad 522 via at least a bond wire. The bond pad 422, the I/O bond pad 442, the bond pad 522, and the I/O bond pad 542 can use a wire bond type selected from a group consisting of ball bonds, stitch bonds on bonding pad, and stitch bonds on ball. In addition, the bond pad 422 also can be electrically connected to the I/O bond pad 442 via a plurality of bond wires, and one of the bond pad 422 and the I/O bond pad 442 can comprise at least a multiple bond site. The bond pad 522 also can be electrically connected to the I/O bond pad 542 via a plurality of bond wires, and one of the bond pad 522 and the I/O bond pad 542 can comprise at least a multiple bond site. Please note that the above embodiments are only for illustration purposes and are not meant to be limitations of the present invention.

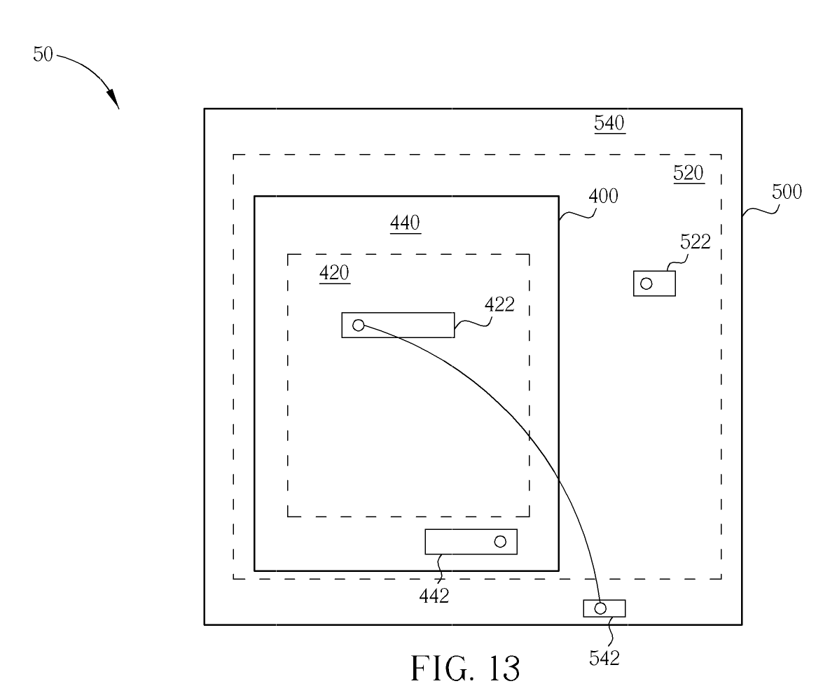

Please refer to FIG. 13. FIG. 13 shows a simplified diagram of a semiconductor device 50 in accordance with a fifth embodiment of the present invention. As shown in FIG. 13, the semiconductor device 50 also comprises the first semiconductor die 400 and the second semiconductor die 500 in the fourth embodiment of the present invention shown in FIG. 9, wherein the first semiconductor die 400 is stacked on the second semiconductor die 500. However, the other characteristics and the variations of the semiconductor device 50 are the same as those of the semiconductor device 40 in the fourth embodiment of the present invention, and thus further explanation of the details and operations are omitted herein for the sake of brevity.

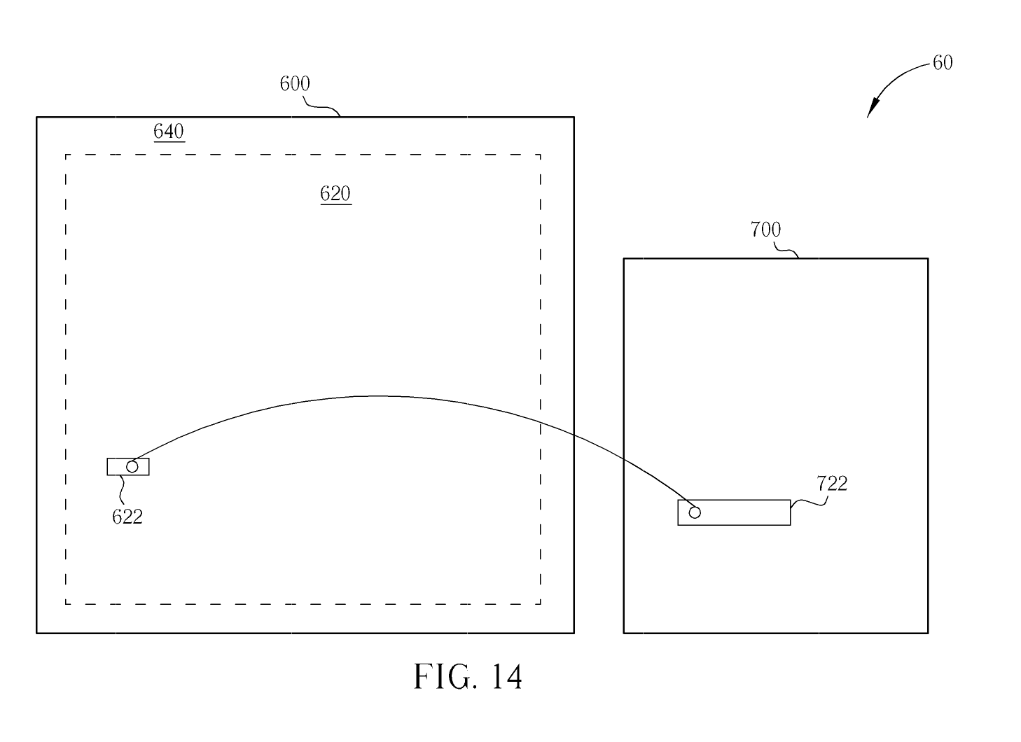

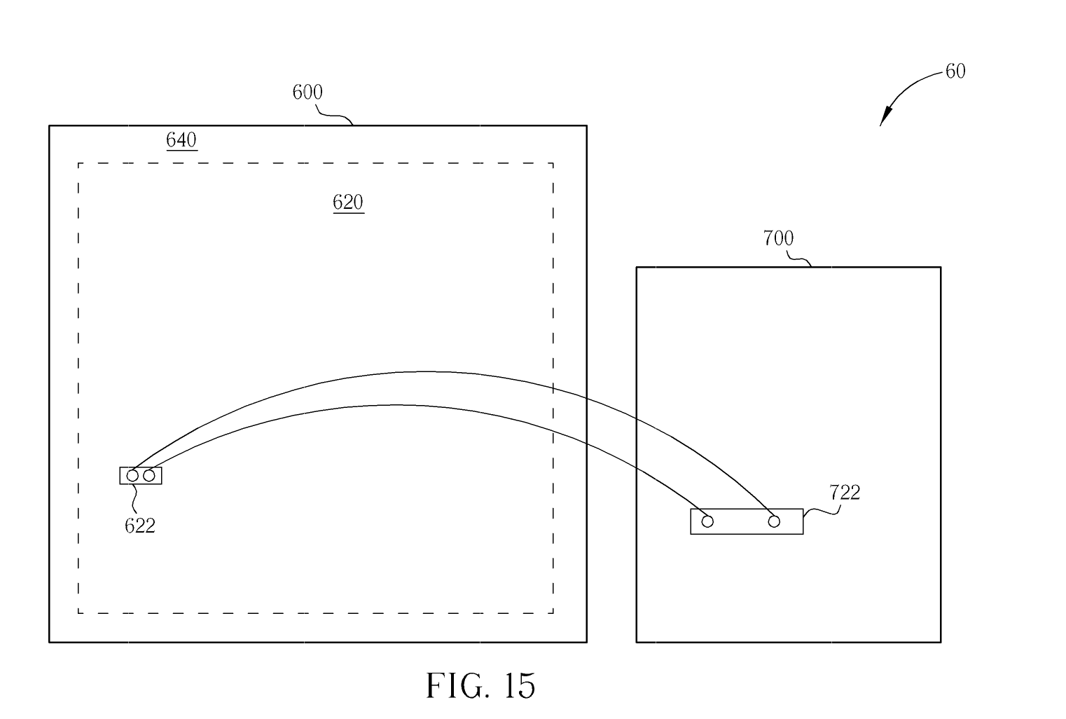

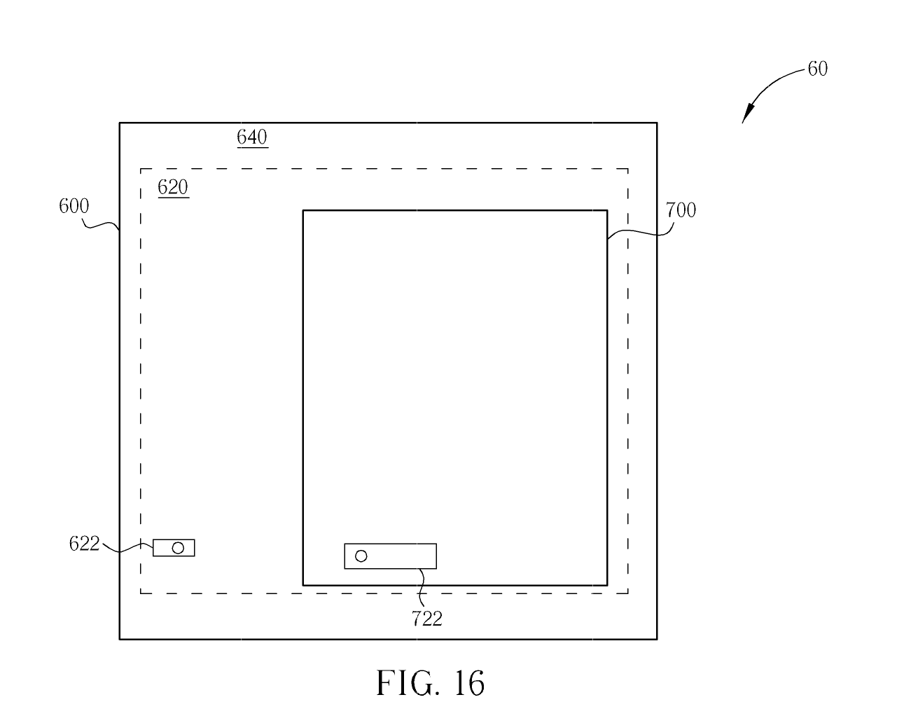

Please refer to FIG. 14. FIG. 14 shows a simplified diagram of a semiconductor device 60 in accordance with a sixth embodiment of the present invention. As shown in FIG. 14, the semiconductor device 60 includes a semiconductor die 600 and a dummy die 700, wherein the semiconductor die 600 and the dummy die 700 are disposed side by side. The semiconductor die 600 comprises a die core 620 having at least a bond pad 622, and an input/output (I/O) periphery 640. The dummy die 700 has at least a bond pad 722 with voltage level equivalent to the bond pad 622, wherein the bond pad 622 is electrically connected to the bond pad 722 via at least a bond wire so as to solve the IR drop of the semiconductor die 600. For example, please refer to FIG. 15. FIG. 15 shows a first variation of the semiconductor device 60. As shown in FIG. 15, the bond pad 622 of the die core 620 can be electrically connected to the bond pad 722 of the dummy die 700 via a plurality of bond wires, and one of the bond pad 622 and the bond pad 722 can comprise at least a multiple bond site. The bond pad 622 and the bond pad 722 can use a wire bond type selected from the group consisting of ball bonds, stitch bonds on bonding pad, and stitch bonds on ball. Please note that the above embodiments are only for illustration purposes and are not meant to be limitations of the present invention. For example, the dummy die 700 also can be stacked on the semiconductor die 600 as shown in FIG. 16. In addition, the dummy die 700 shown in FIG. 14, FIG. 15, and FIG. 16 also can be replaced by a metal film to attain the same purpose of solving the IR drop of the semiconductor die 600. Please note that the above embodiments are only for illustration purposes and are not meant to be limitations of the present invention.

Briefly summarized, the semiconductor devices disclosed by the present invention are obviously capable of solving the IR drop of the semiconductor die with low cost. Besides for the IR drop problems, the semiconductor devices disclosed by the present invention also can be applied to EMI noise rejections by forming a power/ground shielding wire array to absorb the emitted noise from the semiconductor die.

Those skilled in the art will readily observe that numerous modifications and alterations of the device and method may be made while retaining the teachings of the invention.

What is claimed is:

1. A semiconductor device, comprising:
a semiconductor die, comprising:
a die core, having at least two bond pads with voltage level equivalent to each other and electrically connected to each other via at least a bond wire; and
an input/output (I/O) periphery adjacent to the die core.

2. The semiconductor device of claim 1, wherein the bond pads use a wire bond type selected from a group consisting of ball bonds, stitch bonds on bonding pad, and stitch bonds on ball.

3. The semiconductor device of claim 1, wherein the bond pads are electrically connected to each other via a plurality of bond wires, and one of the bond pads comprises at least a multiple bond site.

4. The semiconductor device of claim 1, wherein the die core further comprises a spare pad opening.

5. A semiconductor device, comprising:
a first semiconductor die, comprising:
a first die core, having at least a bond pad; and
a first input/output (I/O) periphery, having at least an I/O bond pad; and
a second semiconductor die, comprising:
a second die core, having at least a bond pad with voltage level equivalent to the bond pad of the first die core; and
a second I/O periphery, having at least an I/O bond pad;
wherein the bond pad of the first die core is electrically connected to the bond pad of the second die core via at least a bond wire.

6. The semiconductor device of claim 5, wherein the bond pad of the first die core and the bond pad of the second die use a wire bond type selected from a group consisting of ball bonds, stitch bonds on bonding pad, and stitch bonds on ball.

7. The semiconductor device of claim 5, wherein the bond pad of the first die core is electrically connected to the bond pad of the second die core via a plurality of bond wires, and one of the bond pad of the first die core and the bond pad of the second die comprises at least a multiple bond site.

8. The semiconductor device of claim 5, wherein the I/O bond pad of the first I/O periphery with voltage level equivalent to the bond pad of the first die core, and the I/O bond pad of the first I/O periphery is electrically connected to the bond pad of the first die core via at least a bond wire.

9. The semiconductor device of claim 8, wherein the bond pad of the first die core and the I/O bond pad of the first I/O periphery use a wire bond type selected from a group consisting of ball bonds, stitch bonds on bonding pad, and stitch bonds on ball.

10. The semiconductor device of claim 8, wherein the bond pad of the first die core is electrically connected to the I/O bond pad of the first I/O periphery core via a plurality of bond wires, and one of the bond pad of the first die core and the I/O bond pad of the first I/O periphery core comprises at least a multiple bond site.

11. The semiconductor device of claim 10, wherein the I/O bond pad of the second I/O periphery has voltage level equivalent to the bond pad of the second die core, the I/O bond pad of the second I/O periphery is electrically connected to the bond pad of the second die core via a plurality of bond wires, and one of the bond pad of the second die core and the I/O bond pad of the second I/O periphery core comprises at least a multiple bond site.

12. The semiconductor device of claim 8, wherein the I/O bond pad of the second I/O periphery has voltage level equivalent to the bond pad of the second die core, and the I/O bond pad of the second I/O periphery is electrically connected to the bond pad of the second die core via at least a bond wire.

13. The semiconductor device of claim 12, wherein the bond pad of the second die core and the I/O bond pad of the second I/O periphery use a wire bond type selected from a group consisting of ball bonds, stitch bonds on bonding pad, and stitch bonds on ball.

14. The semiconductor device of claim 12, wherein the bond pad of the second die core is electrically connected to the I/O bond pad of the second I/O periphery core via a plurality of bond wires, and one of the bond pad of the second die core and the I/O bond pad of the second I/O periphery core comprises at least a multiple bond site.

15. The semiconductor device of claim 5, wherein the first semiconductor die and the second semiconductor die are disposed side by side.

16. The semiconductor device of claim 5, wherein the first semiconductor die is stacked on the second semiconductor die or the second semiconductor die is stacked on the first semiconductor die.

17. A semiconductor device, comprising:
a first semiconductor die, comprising:
a first die core, having at least a bond pad; and
a first input/output (I/O) periphery, having at least an I/O bond pad; and
a second semiconductor die, comprising:
a second die core, having at least a bond pad with voltage level equivalent to the bond pad of the first die core; and
a second I/O periphery, having at least an I/O bond pad with voltage level equivalent to the bond pad of the first die core;
wherein the bond pad of the first die core is electrically connected to the I/O bond pad of the second I/O periphery via at least a bond wire.

18. The semiconductor device of claim 17, wherein the bond pad of the first die core and the I/O bond pad of the second I/O periphery use a wire bond type selected from a group consisting of ball bonds, stitch bonds on bonding pad, and stitch bonds on ball.

19. The semiconductor device of claim 17, wherein the bond pad of the first die core is electrically connected to the I/O bond pad of the second I/O periphery via a plurality of bond wires, and one of the bond pad of the first die core and the I/O bond pad of the second I/O periphery comprises at least a multiple bond site.

20. The semiconductor device of claim 17, wherein the I/O bond pad of the first I/O periphery has voltage level equivalent to the bond pad of the first die core, and the I/O bond pad of the first I/O periphery is electrically connected to the bond pad of the first die core via at least a bond wire.

21. The semiconductor device of claim 20, wherein the bond pad of the first die core and the I/O bond pad of the first I/O periphery use a wire bond type selected from a group consisting of ball bonds, stitch bonds on bonding pad, and stitch bonds on ball.

22. The semiconductor device of claim 20, wherein the bond pad of the first die core is electrically connected to the I/O bond pad of the first I/O periphery core via a plurality of bond wires, and one of the bond pad of the first die core and the I/O bond pad of the first I/O periphery core comprises at least a multiple bond site.

23. The semiconductor device of claim 22, wherein the I/O bond pad of the second I/O periphery has voltage level equivalent to the bond pad of the second die core, the I/O bond pad of the second I/O periphery is electrically connected to the bond pad of the second die core via a plurality of bond wires, and one of the I/O bond pad of the second I/O periphery and the bond pad of the second die core comprises at least a multiple bond site.

24. The semiconductor device of claim 20, wherein the I/O bond pad of the second I/O periphery has voltage level equivalent to the bond pad of the second die core, and the I/O bond pad of the second I/O periphery is electrically connected to the bond pad of the second die core via at least a bond wire.

25. The semiconductor device of claim 24, wherein the bond pad of the second die core and the I/O bond pad of the second I/O periphery use a wire bond type selected from a group consisting of ball bonds, stitch bonds on bonding pad, and stitch bonds on ball.

26. The semiconductor device of claim 24, wherein the bond pad of the second die core is electrically connected to the I/O bond pad of the second I/O periphery core via a plurality of bond wires, and one of the bond pad of the second die core and the I/O bond pad of the second I/O periphery core comprises at least a multiple bond site.

27. The semiconductor device of claim 17, wherein the first semiconductor die and the second semiconductor die are disposed side by side.

28. The semiconductor device of claim 17, wherein the first semiconductor die is stacked on the second semiconductor die or the second semiconductor die is stacked on the first semiconductor die.

29. A semiconductor device, comprising:
a semiconductor die, comprising:
a die core, having at least a bond pad; and
an input/output (I/O) periphery; and
a dummy die, having at least a bond pad with voltage level equivalent to the bond pad of the die core of the semiconductor die;
wherein the bond pad of the die core of the semiconductor die is electrically connected to the bond pad of the dummy die via at least a bond wire.

30. The semiconductor device of claim 29, wherein the bond pad of the die core of the semiconductor die and the bond pad of the dummy die use a wire bond type selected from a group consisting of ball bonds, stitch bonds on bonding pad, and stitch bonds on ball.

31. The semiconductor device of claim 29, wherein the bond pad of the die core of the semiconductor die is electrically connected to the bond pad of the dummy die via a plurality of bond wires, and one of the bond pad of the die core of the semiconductor die and the bond pad of the dummy die comprises at least a multiple bond site.

32. The semiconductor device of claim 29, wherein the semiconductor die and the dummy die are disposed side by side.

33. The semiconductor device of claim 29, wherein the dummy die is stacked on the semiconductor die.

34. A semiconductor device, comprising:
a semiconductor die, comprising:
a die core, having at least a bond pad; and
an input/output (I/O) periphery; and
a metal film, having at least a bond pad with voltage level equivalent to the bond pad of the die core of the semiconductor die;
wherein the bond pad of the die core of the semiconductor die is electrically connected to the bond pad of the metal film via at least a bond wire.

35. The semiconductor device of claim 34, wherein the bond pad of the die core of the semiconductor die and the bond pad of the metal film use a wire bond type selected from a group consisting of ball bonds, stitch bonds on bonding pad, and stitch bonds on ball.

36. The semiconductor device of claim 34, wherein the bond pad of the die core of the semiconductor die is electrically connected to the bond pad of the metal film via a plurality of bond wires, and one of the bond pad of the die core of the semiconductor die and the bond pad of the metal film comprises at least a multiple bond site.

37. The semiconductor device of claim 34, wherein the semiconductor die and the metal film are disposed side by side.

38. The semiconductor device of claim 34, wherein the metal film is stacked on the semiconductor die.
